(19) United States
(12) Patent Application Publication
(10) Pub. No.: US 2025/0266117 A1
(43) Pub. Date: Aug. 21, 2025

(54) COMPUTER-IMPLEMENTED METHOD FOR TESTING LOGIC CIRCUIT IMPLEMENTING THE CACHE FUNCTION

(71) Applicant: STMicroelectronics International N.V., Geneva (CH)

(72) Inventors: Alessandro BASTONI, Aix en Provence (FR); Yvan LEGOUPIL, Mulsanne (FR); Moise GERGAUD, Yvré L'evêque (FR)

(73) Assignee: STMicroelectronics International N.V., Geneva (CH)

(21) Appl. No.: 19/049,364

(22) Filed: Feb. 10, 2025

(30) Foreign Application Priority Data
Feb. 21, 2024 (FR) FR2401695

(51) Int. Cl. G11C 29/20; G11C 29/12; G11C 29/14

(52) U.S. Cl. CPC G11C 29/20; G11C 29/1201; G11C 29/14

(57) ABSTRACT

A computer-implemented method for testing an instruction cache logic circuit of an integrated circuit, comprising: storing in the cache logic circuit a sequence of instructions including M instructions; reading an initial counter value of a cache access counter; executing the sequence of instructions and, for each instruction executed from the cache logic circuit, incrementing the current counter value of the counter; reading a final counter value of the counter; blocking an execution of instructions unintended by the test for a period lasting from reading the initial counter value until reading the final counter value; subtracting the initial counter value from the final counter value, and comparing the result of said subtraction with the value M.

### BACKGROUND

### Technical Field

Embodiments and implementations relate to the means forming a cache memory, in particular the logic circuits implementing the integrated circuit cache function, and more particularly tests of these logic circuits.

### Description of the Related Art

The cache memory is a storage space of an integrated circuit used for storing instructions, in this case we talk about an instruction cache memory, or for storing data, in this case we talk about a data cache memory. A cache memory may be formed by memory cells such as “SRAM” or “DRAM” type memory cells. Logic circuits (also known as “Cache logic”) may also implement the cache function, i.e., replicate the operation of a cache memory.

### BRIEF SUMMARY

Throughout the service life of the integrated circuit, such logic circuits implementing the cache function (which could be referred to hereinafter more simply by the terms “cache logic circuit” or “cache logic”) could feature hardware defects related to wear thereof.

When these logic circuits are used in the context of applications compliant with functional safety standards or using safety functions, tests of the logic circuits are periodically performed to detect these hardware defects, in particular permanent defects. Indeed, these defects typically result in a corruption of the data stored by the logic circuits and therefore generate a dysfunction of the integrated circuit.

Unlike memory cells the defects of which could be detected and possibly corrected though the use of parity bits or error correction codes for example, the cache logic circuits might require other solutions enabling detection of defects thereof.

In particular, these other solutions may comprise the use of “BIST” systems (acronym for “Built-in self-test” which means “integrated auto-test”) known to enable the detection of defects of cache memories and logic circuits, or the implementation of a cache redundancy in these logic circuits, or the tests based on the use of software.

Nevertheless, the “BIST” systems and the implementation of a cache redundancy are relatively expensive solutions and, consequently, testing cache logic circuits by software remains the favored solution.

A conventional test of cache logic circuits by software is typically preceded by an initialization of these logic circuits which consists in particular in emptying the content in memory to allow executing the test in a “deterministic” way.

In other words, the test executed on the cache logic circuits following the initialization of these logic circuit leads to a result allowing determining whether the logic circuits have defects, in contrast with a result that would have been obtained by tests performed on logic circuits the content of which has not been emptied.

Hence, this test type prevents the user from profiting from the storage of such cache logic circuits after each execution of the test since the content of these circuits is emptied before each test and therefore it is necessary to store the instructions or the data again at the end of each test.

Thus, there is a need to provide solutions which allow detecting defects of cache logic circuits and which do not have the aforementioned drawbacks.

A cache logic circuit may be intended to store instructions. This logic circuit is then referred to as an instruction cache logic circuit or more simply an “instruction cache logic”.

A cache logic circuit may be intended to store data. This logic circuit is then referred to as a data cache logic circuit or more simply a “data cache logic”.

According to an implementation of one aspect, relating to testing of an instruction cache logic, a method is provided for testing an instruction cache logic circuit of an integrated circuit, comprising:
storing in the cache logic circuit a sequence of instructions including M instructions,
reading an initial counter value of a cache access counter (“hit counter” in English)
executing the sequence of instructions, and, for each instruction executed from the cache logic circuit, incrementing the current counter value of the cache access counter,
reading a final counter value of the cache access counter,
blocking the unintended execution of instructions by the test for a period lasting from reading the initial counter value until reading the final counter value,
subtracting the initial counter value from the final counter value, and
comparing the result of said subtraction with the value M.

In various embodiments, the above method can be implemented in embedded electronics including one or more processors or otherwise implemented by a computing system or device.

Advantageously, the aforementioned blocking is carried out by deactivating the interruptions that might lead to an unintended execution of additional and/or different instructions. The unintended execution of these instructions might trigger an additional count by the cache access counter and might thus modify the result of the test. Thus, by deactivating these interruptions, the modification of the result of the test by the unintended execution of instructions is prevented, which therefore allows increasing the reliability of the test.

Such a method allows determining when the logic circuit is defective from the values of the cache access counter (“hit counter”).

Indeed, one could consider that this logic circuit is not defective if the result of the subtraction is equal to the number M of instructions. Conversely, the comparison allows indicating the presence of a defect of the logic circuit if this result is different from M.

Such a method allows performing a test of the logic circuit implementing the cache function by software means without requiring emptying the content of the logic circuit.

Hence, the method according to this aspect allows detecting a defect of the logic circuit while allowing continuing to use the instructions already stored in this logic circuit without having to store them again.

Moreover, the method according to this aspect allows avoiding resorting to hardware solutions which could be expensive and have a complex design.

While the implementation of this aspect that has just been mentioned provides for one single execution of the sequence of the M instructions, it would be possible, in another implementation, to provide for a looped processing, i.e., N (N greater than one in this case while N was equal to 1 in the previous implementation) executions of the sequence of M instructions with, at the end, a comparison of the result of the aforementioned subtraction with the value of the product N×M, to determine the presence or the absence of defects of the instructions cache logic circuit.

According to an implementation of another aspect, relating to testing of a data cache logic, a method is provided for testing a data cache logic circuit of an integrated circuit, the integrated circuit including a first memory and a second memory, the method comprising:
“storing at least one piece of data in at least one memory location of the second memory,”
storing a sequence of instructions in the first memory, the sequence of instructions including at least one instruction for storing in the data cache logic circuit the address of said at least one memory location and the corresponding data stored at this memory location and at least one instruction for reading the addresses and the data of the data cache logic circuit,
reading a first initial counter value of a cache access counter (“hit counter”), and/or a second initial counter value of a cache failure counter (“miss counter”), (the first initial counter value and the second initial counter value may be identical or different),
executing the sequence of instructions and, for each store instruction and each read instruction:
   incrementing the current counter value of the cache access counter (“hit counter”) when one of the addresses read in the data cache logic circuit corresponds to the address of said at least one memory location of the second memory,
   and/or incrementing the current counter value of the cache failure counter (“miss counter”) when none of the addresses read in the data cache logic circuit corresponds to the address of said at least one memory location of the second memory,
reading a first final counter value of the cache access counter and/or a second final counter value of the cache failure counter,
blocking a data reading unintended by the test for a period lasting from reading the first initial counter value and/or the second initial counter value until reading the first final counter value and/or the second final counter value,
subtracting the first initial counter value from the first final counter value to obtain a first result and/or subtracting the second initial counter value from the second final counter value to obtain a second result, and
comparing said first result with a value equal to the number of read instructions contained in the sequence of instructions and/or said second result with a value equal to 0.

In various embodiments, the above method can be implemented in embedded electronics including one or more processors or otherwise implemented by a computing system or device.

By analogy with what has been mentioned for the instruction cache logic circuit, the blocking mentioned herein is carried out by deactivating the interruptions that might lead to an unintended reading by the test of the data stored in the data cache logic circuit. The unintended reading of these data might trigger an additional count by the cache access counter (“hit counter”) or by the cache failure counter (“miss counter”) and might thus modify the result of the test. By deactivating these interruptions, the modification of the result of the test by the unintended reading of data is thus prevented, which therefore allows increasing the reliability of the test.

By analogy with what has been mentioned before, the method according to this aspect allows determining when the data cache logic circuit is defective from the values of the cache access counter and/or of the cache failure counter.

Indeed, one could consider that the data cache logic circuit functions properly if the first result is equal to the number of read instructions present in the sequence of instructions and if the second result is equal to 0. Conversely, the comparison allows indicating the presence of a defect of the data cache logic circuit.

The aforementioned other advantages relating to the test method and to the reliability of the test of an instruction cache logic circuit are also valid in the case of the method for testing a data cache logic circuit.

Moreover, while the implementation of this other aspect that has just been mentioned provides for one single execution of the sequence of instructions, it would be possible, in another implementation, to provide for a looped processing, i.e., N (N greater than one in this case while N was equal to 1 in the previous implementation) executions of the sequence of instructions with, at the end, a comparison of the result of the aforementioned subtraction with the value equal to N times the number of read instructions contained in the sequence of instructions, to determine the presence or the absence of defects of the data cache logic circuit.

Advantageously, the method according to this other aspect may comprise interrupting the sequence of instructions if the data read in the data cache logic circuit at said address is different from the data stored in the memory location of the second memory located at this address.

The verification of the data stored by the data cache logic circuit during the execution of the instructions allows detecting a defect of this cache logic circuit before determining the result of the test from the initial and final counter values.

Thus, it is possible to shorten the duration of the test of the data cache logic circuit when a defect is detected by comparing the piece of data stored by this logic circuit and that one stored in the second memory for the same address.

According to still another aspect, a computer program product is provided configured to test an (instruction or data) cache logic circuit of an integrated circuit, the computer program product comprising instructions which, when the program is executed by a computer, cause the latter to implement the method for testing an instruction cache logic circuit defined before or the method for testing a data cache logic circuit defined before.

According to still another aspect, a computer system is provided comprising:
a memory comprising a computer program product as defined before,
a processing unit configured to execute said computer program product.

### BRIEF DESCRIPTION OF THE SEVERAL VIEWS OF THE DRAWINGS

Other advantages and features of the disclosure will become apparent upon examining the detailed description of non-limiting embodiments and implementations, and from the appended drawings, wherein:

FIG. 1, FIG. 2, FIG. 3, and FIG. 4 schematically illustrate implementations and embodiments of the disclosure.

### DETAILED DESCRIPTION

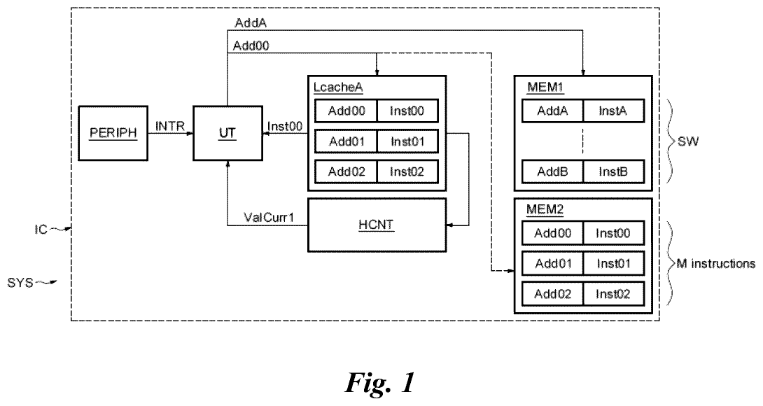

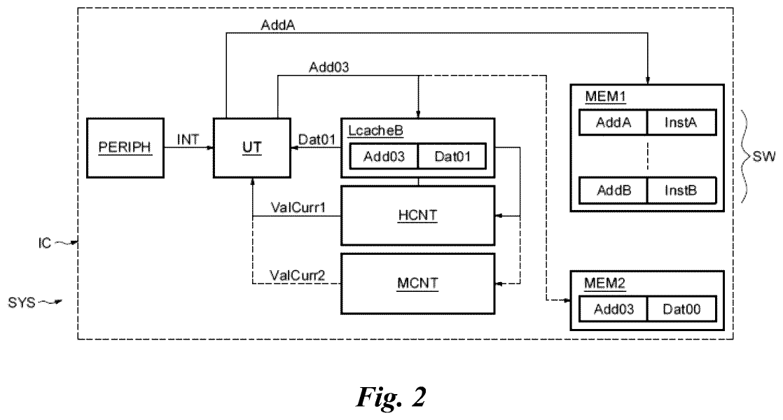

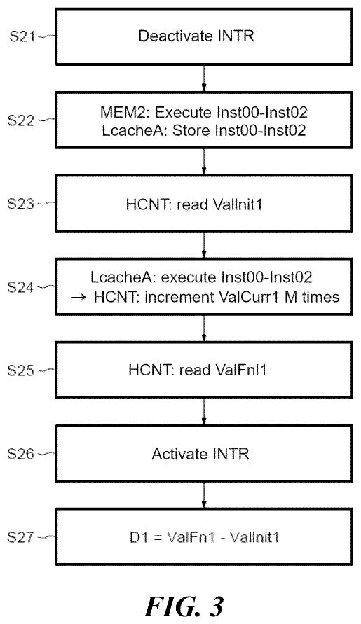

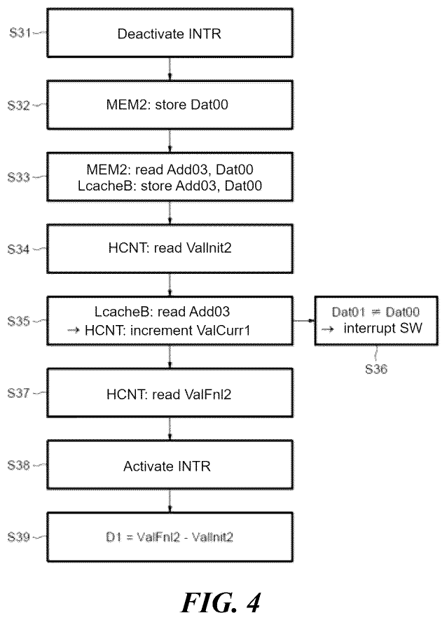

Next, FIGS. 1 and 3 relate to testing of an instruction cache logic and FIGS. 2 and 4 relate to testing of a data cache logic, and that being so in the context of a loop-free processing (N=1).

FIG. 1 schematically illustrates a computer system SYS comprising an integrated circuit IC according to an embodiment of the disclosure.

The integrated circuit IC comprises an instruction cache logic circuit LcacheA. This logic circuit LcacheA implements the cache function.

Such a logic circuit is known to a person skilled in the art by the name “Cache logic” in English and allows storing instructions. The structure and the operation of such a cache logic circuit LcacheA are understood as common knowledge in the state of art and will not therefore be detailed in the present application. Next, the term “logic circuit LcacheA” will be simply used sometimes to refer to the instruction cache logic circuit LcacheA implementing the cache function, for simplicity.

The integrated circuit IC also comprises a first memory MEM1, such as a RAM memory (standing for “Random access memory”) for example and a processing unit UT, such as a processor.

The first memory MEM1 includes a dedicated space for storing a computer program product, for example an embedded system software, and a dedicated space for storing a sequence of instructions SW. For example, the sequence of instructions SW comprises several instructions denoted InstA to InstB stored in the memory locations at the addresses AddA to AddB. The embedded system software is configured to test the logic circuit LcacheA, in particular thanks to the execution of the sequence of instructions SW.

The processing unit is configured to execute the embedded software so as to implement the method described later on with reference to FIG. 3. To do so, the processing unit UT is connected to the first memory MEM1.

The integrated circuit IC also includes a second memory MEM2, which may be a RAM memory for example, configured to store a sequence of instructions, different from the sequence of instructions SW recorded in the first memory MEM1. For example, the sequence of instructions stored in the second memory MEM2 comprises M=3 instructions Inst00, Inst01 and Inst02.

In particular, each instruction of the sequence of instructions is stored at an address of a memory location of the second memory MEM2. For example, the address Add00 of the memory location includes the instruction Inst00.

The logic circuit LcacheA is configured to store an address of a memory location of the second memory MEM2 and the instruction stored in the second memory MEM2 at this memory location.

The processing unit UT is configured to execute the instructions stored in the logic circuit LcacheA, for example the instruction Inst00 associated with the address Add00.

Furthermore, the integrated circuit IC comprises a counter HCNT.

This counter HCNT is typically known by a person skilled in the art as “hit counter” or “cache access counter.”

This counter HCNT is configured to increment a counter value ValCurr1 each time the processing unit UT executes an instruction stored in the logic circuit LcacheA.

The processing unit UT is also configured to read the counter value ValCurr1 of the counter HCNT.

FIG. 3 schematically illustrates an example of a method, based on the use of the counter HCNT, implemented by a computer, in particular by an embedded software, for testing the logic circuit LcacheA of the integrated circuit IC described before with reference to FIG. 1. It is assumed that the initial counter value of the first counter HCNT amounts to 0 before implementation of the method, although this initial counter value could be different from 0.

The method comprises a step S21 of blocking the execution of instructions unintended by the test.

More particularly, interruptions INTR (FIG. 1), generated for example by peripherals PERIPH or internal resources of the processing unit UT, could lead to an unintended execution of these instructions by the processing unit UT. The unintended execution of these instructions might trigger an additional count by the counter HCNT and might thus modify the result of the test.

In this respect, the aforementioned blocking may be performed by deactivation of the interruptions INTR by the processing unit UT.

Such a deactivation is a conventional operation known per se.

This blocking, which allows increasing the reliability of the test, is performed until step S26 of reactivating the interruptions.

The method comprises a step S22 in which the processing unit UT executes the sequence of instructions stored in the second memory MEM2.

In this example, the sequence of instructions comprises M=3 instructions Inst00, Inst01 and Inst02.

Step S22 also comprises storing in the logic circuit LcacheA the sequence of instructions Inst00, Inst01 and Inst02.

The method also comprises a step S23 of reading an initial counter value ValInit1 of the first counter HCNT.

The initial counter value ValInit1 is read by the processing unit UT.

The method comprises a step S24 of executing the sequence of instructions Inst00, Inst01 and Inst02.

During this step S24, the instructions Inst00, Inst01 and Inst02 are read from the logic circuit LcacheA and executed by the processing unit UT.

Step S24 comprises, each time an instruction is executed, incrementing the current counter value ValCurr1 of the counter HCNT when the executed instruction is an instruction stored in the logic circuit LcacheA.

Nonetheless, it might happen, in the event of a defect of the logic circuit LcacheA, that the processing unit UT does not execute some or all the instruction stored in the logic circuit LcacheA. In this case, the current counter value ValCurr1 is not incremented.

Afterwards, the method comprises a step S25 of reading a final counter value ValFnl1 of the counter HCNT. In the absence of any defect of the logic circuits LcacheA, the final counter value ValFnl1 amounts to 3 in this example.

The final counter value ValFnl1 is read by the processing unit UT.

Afterwards, the method comprises step S26 (mentioned hereinbefore) of activating the interruptions INTR, in particular when these interruptions INTR have been deactivated in step S21.

The method comprises a step S27 of subtracting the initial counter value ValInit1 from the final counter value ValFnl1. The result D1 of this subtraction, which therefore amounts to 3 in this example in the absence of any defect of the logic circuit LcacheA, is stored in a third variable.

Step S27 also comprises comparing the result D1 with the number M of instructions of the sequence of instructions.

The result of this comparison allows concluding on an absence of any defect of the logic circuit LcacheA if D1 is equal to M or on a defect if D1 is different from M.

Such a method allows performing a test of the logic circuit LcacheA by software means without requiring emptying the content of the logic circuit. Hence, it is possible to detect a defect of the logic circuit while allowing continuing to use the instructions already stored in this logic circuit without having to store them again.

Thus, we avoid resorting to hardware solutions which could be expensive and have a complex design.

FIG. 2 schematically illustrates a system SYS comprising an integrated circuit IC according to another embodiment of the disclosure.

The integrated circuit IC comprises a data cache logic circuit LcacheB. This logic circuit implements the cache function. Herein again, such a logic circuit is known to a person skilled in the art as “Cache logic” in English and allows storing data. Although they could be different from those of a cache logic circuit LcacheA described before with reference to FIG. 1, the structure and the operation of such a logic circuit LcacheB are classic and will not therefore be detailed in the present application.

Next, the term “logic circuit LcacheB” will be simply used sometimes to refer to the data cache logic circuit LcacheB implementing the cache function, for simplicity.

The integrated circuit IC also comprises a first memory MEM1, and a processing unit UT such as a processor.

The processing unit UT and the first memory MEM1 may be the same as those described before with reference to FIG. 1. The embedded system software (sequence of instructions SW) stored in the first memory MEM1 is this time configured to test the logic circuit LcacheB.

The processing unit UT is configured to execute the embedded software so as to implement the method described hereinafter with reference to FIG. 4.

Furthermore, the integrated circuit IC includes a second memory MEM2. The second memory MEM2 is configured to store a piece of data at an address of a memory location of the second memory MEM2. For example, the piece of data Dat00 is stored at the memory location located at the address Add03.

The logic circuit LcacheB is configured to store an address of a memory location of the second memory MEM2 and the data stored in the second memory MEM2 at this memory location. For example, in this case, it is assumed that the logic circuit LcacheB is defective and that the data Dat01 stored in this logic circuit LcacheB is different from the data Dat00 stored in the second memory MEM2 at the corresponding address Add03.

The processing unit UT is configured to read the data stored in the logic circuits LcacheB, for example the data Dat01 associated with the address Add03.

The integrated circuit IC also comprises a counter HCNT and a counter MCNT.

The counter HCNT, herein again referred to by the terms “cache access counter” (“Hit counter”), is configured to increment a counter value ValCurr1 each time the processing unit UT reads a piece of data stored in the logic circuit LcacheB.

The counter MCNT, typically known by a person skilled in the art as “miss counter” or “cache failure counter,” is configured to increment a counter value ValCurr2 each time the processing unit UT reads a piece of data stored in the second memory MEM2 and this piece of data is not stored in the logic circuit LcacheB. The processing unit UT is also configured to read the counter value ValCurr1 of the counter HCNT and the counter value ValCurr2 of the counter MCNT.

FIG. 4 schematically illustrates an example of a method, based on the use of the counter HCNT, implemented by a computer, in particular an embedded software, for testing the logic circuit LcacheB of the integrated circuit IC described before with reference to FIG. 2.

It is herein assumed that the initial counter value ValCurr1 of the counter HCNT amounts to 0, although this initial counter value could be different from 0.

The method comprises a step S31 of blocking a data reading unintended by the test.

More particularly, by analogy with what has been described for step S21 of FIG. 3, interruptions INTR (FIG. 2), generated for example by peripherals PERIPH or internal resources of the processing unit UT, could to an unintended reading of these data by the processing unit UT. The unintended reading of these data might trigger an additional count by the counter HCNT and might thus modify the result of the test.

In this respect, the aforementioned blocking may be performed by deactivation of the interruptions INTR by the processing unit UT.

Such a deactivation is a conventional operation known per se.

This blocking, which allows increasing the reliability of the test, is performed until step S38 of reactivating the interruptions.

The method comprises a step S32 of storing in at least one memory location of the second memory MEM2 at least one piece of data, for example the data Dat00 at the memory location at the address Add03 of the second memory MEM2.

Afterwards, the method comprises a step S33 including reading the data Dat00 by the processing unit UT from the memory location of the second memory MEM2 at the address Add03 and storing the address Add03 of the memory location and the data Dat00 stored in this memory location of the second memory MEM2, in the logic circuit LcacheB.

The method comprises a step S34 of reading the initial counter value ValInit2 of the counter HCNT of the integrated circuit IC.

The initial counter value ValInit2, which amounts for example to 1 at this stage, is read by the processing unit UT.

The method comprises a step S35 comprising reading the addresses and the data of the logic circuit LcacheB.

Step S35 comprises incrementing the current counter value ValCurr1 of the counter HCNT when the processing unit UT reads a piece of data stored in the logic circuit LcacheB.

Nonetheless, a cache failure might happen in the event of defect of the logic circuit LcacheB and the processing unit UT might read the data stored at the memory location of the memory MEM2 while the latter is not stored in the logic circuit LcacheB. In this case, the current counter value ValCurr1 is not incremented.

The method comprises a step S36 of interrupting the sequence of instructions SW if the data read in the logic circuit LcacheB at the address of the memory location of the second memory MEM2 is different from the data stored in the memory location of the second memory MEM2 located at this address. Indeed, a piece of data stored in the logic circuit LcacheB could be corrupted in the event of defect and this piece of data does not therefore corresponds to that one stored in the second memory MEM2 at the corresponding address.

More specifically, in the example illustrated in FIGS. 2 and 4, the data read at the address Add03 from the logic circuit LcacheB during the execution of the sequence of instructions is the data Dat01 which is different from the data Dat00 stored in the memory location of the second memory MEM2 located at this address Add03. Consequently, the execution of the sequence of instruction SW by the processing unit UT is interrupted (step S36) and allows indicating that a defect of the logic circuit LcacheB has been detected.

Next, it will be considered that no execution of the sequence of instructions has been interrupted.

Afterwards, the method comprises a step S37 of reading a final counter value ValFnl2 of the counter HCNT.

The final counter value ValFn12 is read by the processing unit UT. In this example, in the absence of cache failure, the final counter value ValFn12 amounts to 2 since the initial value has been deemed equal to 1.

The method comprises a step S38 of activating the interruptions INTR similar to step S26 described before with reference to FIG. 3.

The method comprises a step S39 similar to step S27 described before in connection with FIG. 3. Step S39 comprises subtracting the initial counter value ValInit2 from the final counter value ValFn12 to obtain a first result D1 which herein amounts to 2−1=1. Step S39 comprises comparing the first result D1 with the number of read instructions contained in the sequence of instructions SW.

The result of this comparison then allows concluding, assuming that no execution of the sequence of instructions has been interrupted, on an absence of defect of the logic circuit LcacheB since the first result D1 is equal to the expected value which is 1.

The advantages of the method for testing the logic circuit LcacheB are similar to those mentioned for testing the logic circuit LcacheA.

While, in order to test the logic circuit LcacheB, the counter HCNT has been used, it would be possible to also use the counter MCNT (“Miss counter”). The value of the counter MCNT is incremented each time the processing unit UT reads the data Dat00 in the second memory MEM2 and this data is not stored in the logic circuit LcacheB.

And the absence or the presence of defect of this logic circuits would be determined by comparing with 0 the result of the difference between the final counter value and the initial counter value of this counter MCNT.

A computer-implemented method for testing an instruction cache logic circuit (LcacheA) of an integrated circuit (IC) can include: storing in the cache logic circuit (LcacheA) a sequence of instructions including M instructions (Inst00, Inst01, Inst02), reading an initial counter value (ValInit1) of a cache access counter (HCNT), executing the sequence of instructions N times, with N being greater than or equal to 1, and, for each instruction executed from the cache logic circuit (LcacheA), incrementing the current counter value (ValCurr) of the counter (HCNT), reading a final counter value (ValFnl) of the counter (HCNT), blocking the unintended execution of instructions by the test for a period lasting from reading the initial counter value (ValInt1) until reading the final counter value (ValFnl), subtracting the initial counter value (ValInit1) from the final counter value (ValFnl), and comparing the result of said subtraction (D1) with a value equal to the product N×M.

A computer-implemented method for testing a data cache logic circuit (LcacheB) of an integrated circuit (IC), the integrated circuit including a first memory (MEM1) and a second memory (MEM2), the method can include: storing in at least one memory location of the second memory at least one piece of data (Dat00), storing a sequence of instructions (SW) in the first memory (MEM1), the sequence of instructions including at least one instruction for storing in the cache logic circuit (LcacheB) the address (Add03) of said at least one memory location and the corresponding data (Dat00) stored at this memory location and at least one instruction for reading the addresses and the data of the data cache logic circuit (LcacheB), reading a first initial counter value of a cache access counter (HCNT) and/or a second initial counter value of a cache failure counter (MCNT), executing the sequence of instructions (SW) N times, with N greater than or equal to 1, and, for each store instruction and each read instruction: incrementing the current counter value (ValCurr1) of the cache access counter (HCNT) when one of the addresses read in the cache logic circuit (LcacheB) corresponds to the address of said at least one memory location of the second memory (MEM2), and/or incrementing the current counter value (ValCurr2) of the cache failure counter (MCNT) when none of the addresses read in the cache logic circuit (LcacheB) corresponds to the address of said at least one memory location of the second memory (MEM2), reading a first final counter value (ValFn12) of the cache access counter (HCNT) and/or a second final value of the cache failure counter (MCNT), blocking a data reading unintended by the test for a period lasting from reading the first initial counter value and/or the second initial counter value until reading the first final counter value and/or the second final counter value, subtracting the first initial counter value (ValInit2) from the first final counter value (ValFn12) of the cache access counter (HCNT) to obtain a first result (D1) and/or subtracting the second initial counter value from the second final counter value of the cache failure counter (MCNT) to obtain a second result (D2), and comparing said first result (D1) with a value equal to N times the number of read instructions contained in the sequence of instructions (SW) and/or said second result (D2) with a value equal to 0.

The method can include interrupting the sequence of instructions (SW) if the data read in the means forming the cache memory (Dat01) at said address is different from the data (Dat00) stored in the memory location of the second memory (MEM2) located at this address (Add03).

A computer program product configured to test a cache logic circuit (LcacheA, LcacheB) of an integrated circuit, the computer program product can include instructions which, when the program is executed by a computer, cause the latter to implement one or more of the above methods.

A computer system can include: a memory (MEM1) comprising the above computer program product, a processing unit (UT) configured to execute said computer program product.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A computer-implemented method for testing an instruction cache logic circuit of an integrated circuit, comprising:
storing in the cache logic circuit a sequence of instructions including M instructions;
reading an initial counter value of a cache access counter;
executing the sequence of instructions N times, with N being greater than or equal to 1, and, for each instruction executed from the cache logic circuit, incrementing a current counter value of the counter;
reading a final counter value of the counter;
blocking an unintended execution of instructions by the test for a period lasting from reading the initial counter value until reading the final counter value;
subtracting the initial counter value from the final counter value; and
comparing a result of the subtraction with a value equal to the product of N and M.

2. A computer-implemented method for testing a data cache logic circuit of an integrated circuit, the integrated circuit including a first memory and a second memory, the method comprising:
storing in at least one memory location of the second memory at least one piece of data;
storing a sequence of instructions in the first memory, the sequence of instructions including at least one instruction for storing in the cache logic circuit an address of the at least one memory location and corresponding data stored at the memory location and at least one instruction for reading addresses and data of the data cache logic circuit;
reading at least one of a first initial counter value of a cache access counter or a second initial counter value of a cache failure counter;
executing the sequence of instructions N times, with N greater than or equal to 1, and, for each store instruction and each read instruction, performing at least one of:
incrementing a current counter value of the cache access counter when one of the addresses read in the cache logic circuit corresponds to the address of the at least one memory location of the second memory; or
incrementing a current counter value of the cache failure counter when none of the addresses read in the cache logic circuit corresponds to the address of the at least one memory location of the second memory;
reading at least one of a first final counter value of the cache access counter or a second final value of the cache failure counter;
blocking a data reading unintended by the test for a period lasting from reading the first initial counter value or the second initial counter value until reading the first final counter value or the second final counter value,
performing at least one of:
subtracting the first initial counter value from the first final counter value of the cache access counter to obtain a first result; or
subtracting the second initial counter value from the second final counter value of the cache failure counter to obtain a second result; and
comparing the first result with at least one of a value equal to N times the number of read instructions contained in the sequence of instructions or the second result with a value equal to 0.

3. The method according to claim 2, comprising interrupting the sequence of instructions if data read in the means forming the cache memory at the address is different from the data stored in the memory location of the second memory located at the address.

4. A computer program product configured to test a cache logic circuit of an integrated circuit, the computer program product comprising instructions which, when the program is executed by a computer, cause the latter to implement the method comprising:
storing in the cache logic circuit a sequence of instructions including M instructions;
reading an initial counter value of a cache access counter;
executing the sequence of instructions N times, with N being greater than or equal to 1, and, for each instruction executed from the cache logic circuit, incrementing a current counter value of the counter;
reading a final counter value of the counter;
blocking an unintended execution of instructions by the test for a period lasting from reading the initial counter value until reading the final counter value;
subtracting the initial counter value from the final counter value; and
comparing a result of the subtraction with a value equal to the product of N and M.

5. A computer system comprising:
a memory storing content; and
a processing unit configured to execute the content to cause the system to perform a method for testing a data cache logic circuit of an integrated circuit, the integrated circuit including a first memory and a second memory, the method comprising:
storing in at least one memory location of the second memory at least one piece of data;
storing a sequence of instructions in the first memory, the sequence of instructions including at least one instruction for storing in the cache logic circuit an address of the at least one memory location and corresponding data stored at the memory location and at least one instruction for reading addresses and data of the data cache logic circuit;
reading at least one of a first initial counter value of a cache access counter or a second initial counter value of a cache failure counter;
executing the sequence of instructions N times, with N greater than or equal to 1, and, for each store instruction and each read instruction, performing at least one of:
incrementing a current counter value of the cache access counter when one of the addresses read in the cache logic circuit corresponds to the address of the at least one memory location of the second memory; or
incrementing a current counter value of the cache failure counter when none of the addresses read in the cache logic circuit corresponds to the address of the at least one memory location of the second memory;
reading at least one of a first final counter value of the cache access counter or a second final value of the cache failure counter;
blocking a data reading unintended by the test for a period lasting from reading the first initial counter value or the second initial counter value until reading the first final counter value or the second final counter value,
performing at least one of:
subtracting the first initial counter value from the first final counter value of the cache access counter to obtain a first result; or
subtracting the second initial counter value from the second final counter value of the cache failure counter to obtain a second result; and
comparing the first result with at least one of a value equal to N times the number of read instructions contained in the sequence of instructions or the second result with a value equal to 0.

6. The system according to claim 5, wherein the method comprises interrupting the sequence of instructions if data read in the means forming the cache memory at the address is different from the data stored in the memory location of the second memory located at the address.
